(19) United States
(12) Patent Application Publication
(10) Pub. No.: US 2026/0047016 A1
(43) Pub. Date: Feb. 12, 2026

(54) Adaptable Video Displays Comprised of Flexible Panels That Can Be Used In Multiple Orientations

(71) Applicant: Production Resource Group, L.L.C., New Windsor, NY (US)

(72) Inventor: Frederic Opsomer, Kortemark (BE)

(21) Appl. No.: 19/104,301

(22) PCT Filed: Aug. 9, 2023
(86) PCT No.: PCT/US2023/029837

§ 371 Date: Feb. 17, 2025

Related U.S. Application Data
(60) Provisional application No. 63/399,090, filed on Aug. 18, 2022.

(51) Int. Cl. H05K 5/02

(52) U.S. Cl. CPC H05K 5/0217

(57) ABSTRACT

Adaptable, flexible video displays are disclosed comprised of flexible fabric or plastic panels for use as portable stadium drapes, hanging backdrops, and the like. Systems and methods for packaging or transporting rolled or folded flexible LED panels of adaptable video displays are also disclosed.

### RELATED APPLICATION

The present application claims priority to U.S. Provisional Application No. 63/399,090, filed Aug. 18, 2022, entitled “Adaptable Video Displays Comprised of Flexible Panels That Can Be Used in Multiple Orientations,” which is incorporated herein by reference in its entirety.

### FIELD OF THE INVENTION

The present disclosure generally relates to LED displays and more specifically to adaptable video displays comprised of flexible panels that can be used in multiple orientations, such as for portable stadium drapes and hanging backdrops.

### BACKGROUND

Sports stadiums and other large venues designed for a specific purpose are often used for other purposes, such as music concerts held in a sports stadium. In adapting the venue to the needs of a unique performance, many types of portable and modifiable staging systems have been proposed and used. With the ever-increasing use of video backdrops for large concerts and other performances, there is a need for easily portable and readily assembled large format, video wall-type displays that are more easily deployed and taken down than conventional video wall display arrays.

The present disclosure describes systems, devices and methods that meet these needs.

### SUMMARY OF THE DISCLOSURE

In one embodiment, an adaptable video displays comprised of one or more flexible display panels. The adaptable video displays include a flexible, foldable and rollable substrate having edges with corners; stretcher connectors disposed at each corner on a back side of said substrate; at least two stretching members configured to extend between opposite stretcher connectors to hold said substrate in a flat, substantially taught state; flexible LED strips disposed on a front side of said substrate forming an array of LED pixels along the front side surface of said substrate; panel-to-panel connectors along each panel edge; and one or more data and power links communicating with said flexible LED strips.

In another embodiment, an adaptable video display system. The adaptable video display system includes a plurality of flexible display panels according to any of claims 1-6, said panels joinable along panel edges in an array to form a video display; a plurality of power supplies, each power supply connectable with at least one said flexible display panel via said data and power links; and a plurality of storage and transport dollies, each dolly mounted on wheels and configured to carry thirty to sixty rolled up flexible display panels and power supplies for at least every two flexible display panels carried by the dolly.

In yet another embodiment, a method for deploying a video display. The method includes providing a plurality of flexible display panels, each said flexible display panel having a flexible LED array on a front side and stretcher connectors in corners on a back side; expanding and stiffening each flexible display panel by placing stretching members in opposed stretcher connectors on each said flexible panel; connecting the flexible display panels along panel edges to form a video display comprised of an array of the plurality of flexible display panels; and positioning said video display as a drape across a plurality of stadium or theater seats, or alternatively hanging said video display in a vertical configuration from a support structure.

### BRIEF DESCRIPTION OF DRAWINGS

For the purpose of illustrating the disclosure, the drawings show aspects of one or more embodiments of the disclosure. However, it should be understood that the present disclosure is not limited to the precise arrangements and instrumentalities shown in the drawings, wherein:

FIG. 1 is a perspective view of an embodiment of an adaptable video display comprised of flexible panels utilized as an LED drape disposed across stadium seating according to the present disclosure.

FIG. 2 is a front view of an alternative embodiment of an adaptable video display comprised of flexible panels hanging from a wall as a video backdrop according to the present disclosure.

FIG. 3 is a front perspective view of an embodiment of an individual flexible LED panel for use in forming adaptable video displays according to the present disclosure.

FIG. 4 is a back perspective view of an embodiment of an individual flexible LED panel according to the present disclosure.

FIG. 5 illustrates a step in a dismantling process for adaptable video displays comprised of flexible panels as disclosed herein.

FIG. 6 illustrates another step in a dismantling process for adaptable video displays comprised of flexible panels as disclosed herein.

FIG. 7 illustrates a further step in a dismantling process for adaptable video displays comprised of flexible panels as disclosed herein.

FIG. 8 is perspective view of an embodiment of a dolly configured to transport and store plural flexible LED panels as disclosed herein.

FIG. 9 illustrates a plurality of dollies as in FIG. 8 packed on trucks for transport.

FIG. 10 is a schematic depiction of an embodiment of a flexible LED panel with serial data and power connections according to the present disclosure.

FIG. 11 is a schematic depiction of an alternative embodiment of a flexible LED panel with parallel data and power connections according to the present disclosure.

### DETAILED DESCRIPTION

Embodiments disclosed herein provide an adaptable video display comprised of flexible panels designed to cover the seated area in an arena or stadium with the flexibility and lightness of a drape fitted with LEDs. Alternative disclosed embodiments also provide LED backdrops for wall-hung applications. In some embodiments, the LED pixel pitch can be as small as 15 mm.

In one implementation, two rotatable glass fiber tubes or rods mounted at the back in the very center of an individual LED drape panel, allow for the drape panel to be stretched and ensure a regular pixel pitch on the landscape image once mounted together. The panel also may be fitted with grommets on the borders of the four sides of the square panel, including additional hook and loop fasteners and an automatic locking system for the flexible panels to be connected together seamlessly. For transport, the two back glass fiber tubes are removed from the corner pieces of the panel, rotated to a parallel position for the LED drape panel to be rolled up and placed in the dolly. Forty-four drape panels can be fit into one dolly sized approximately as 3 m×2.2 m×1.1 m. This configuration allows as many as ten dollies to be carried in a standard truck to save transport volume by as much as 400% and weight savings of approximately 900% compared to transport of conventional concert touring LED screen arrays.

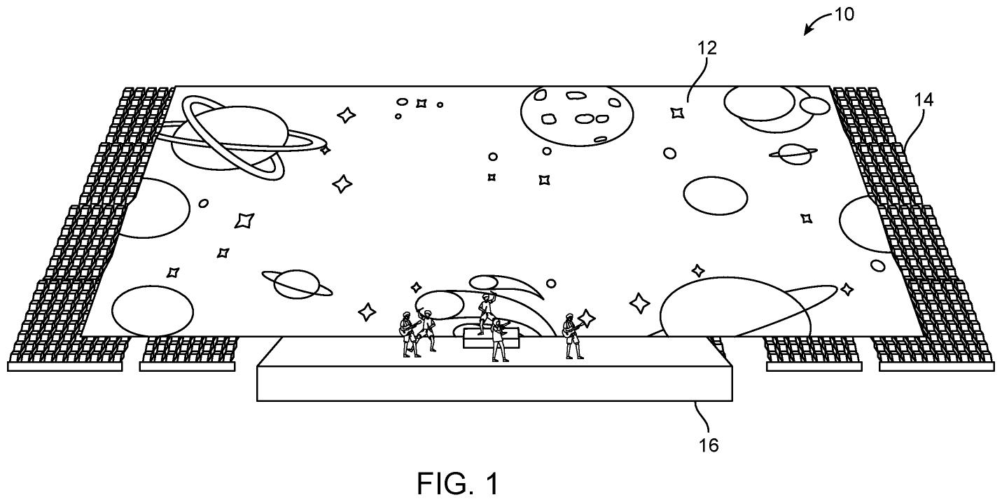

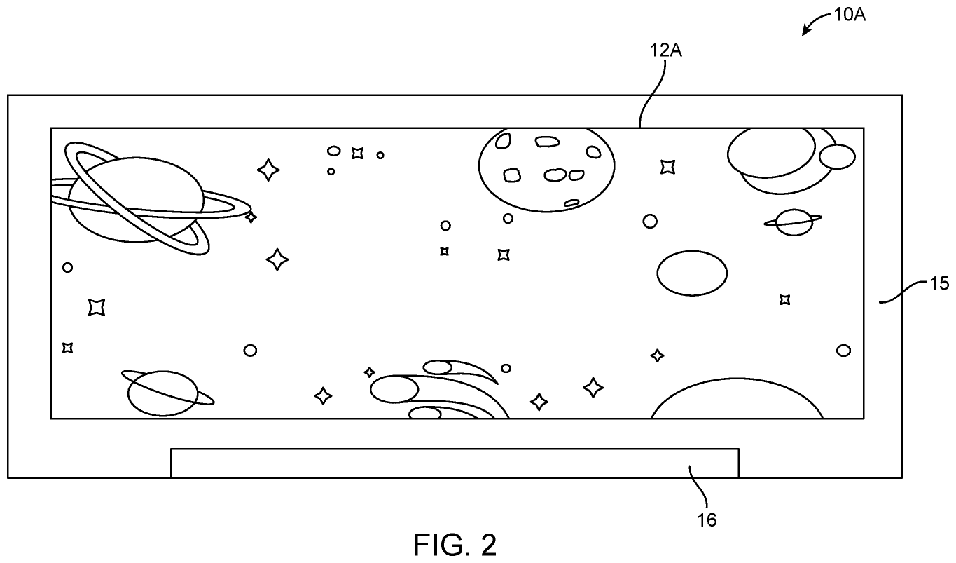

Further features, advantages and details of disclosed embodiments are provided hereinafter with reference to the figures, wherein FIG. 1 illustrates an overall system 10 including an adaptable video display comprised of flexible panels 12 placed over stadium seats 14 as an LED drape in front of performance stage 16. In one alternative embodiment, as illustrated in FIG. 2, alternative system 10A includes an adaptable video display comprised of flexible panels providing a flexible wall-hung LED video backdrop 12A, mounted on wall 15 in front of performance stage 16.

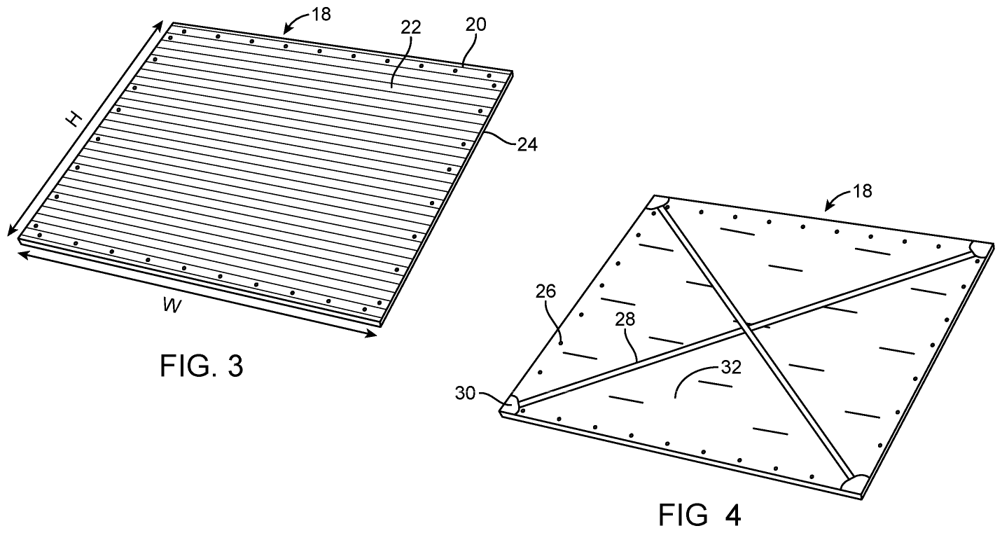

Each of LED drape 12 and wall hung LED video backdrop 12A are made up of flexible LED panels 18 as shown in FIGS. 3 and 4. Each flexible LED panel 18 has on a front side a plurality of preferably parallel rows of flexible LED strips 20 mounted on fabric substrate 22. Preferably fabric substrate 22 is black, although other colors may be used consistent with desired visual appearance. Examples of fabric materials for fabric substrate 22 include polyester, canvas, nylon, polyethylene and polypropylene, and may include fireproofing treatments. Along each side, front and back of LED panels 18 are a series of hook & loop fasteners 24 configured to connect adjoining panels 18 when assembled into an array so as to provide an at least substantially seamless appearance for the overall drape 12 or hung display 12A. Each panel 18 also may be provided with a series of grommeted or otherwise reinforced holes 26 around the periphery to provide additional security for attaching panels together and/or for wind bracing or tie downs.

On the back of each panel 18, as shown in FIG. 4, two stretching members 28, attached together with a pivot at their centers, provide structural stiffness and a flat appearance for the stretched panels. Stretching members 28 may be formed, for example, from fiberglass or other similar, lightweight flexible material as tubes or rods. Corner pieces 30 provided at each corner on the back side of panel 18 provide stretcher connectors configured to receive stretching members 28. Corner pieces 30 may be formed, for example, as a flexible material in a pocket-like configuration, or as loops of cord or webbing or as other types of socket devices that receive ends of stretching members 28. Stretching members 28 are configured to extend between opposite stretcher connectors at corners of fabric substrate 22 to hold the substrate in a flat, substantially taught state so as to present a uniform display surface on the front side. Holes or slits 32 also may be provided in panels to function as rain drains and/or to reduce wind resistance.

In one example, individual panels 18 may have a height (H) of about 1600 mm (63 inches) and a width (W) of about 2000 mm (78.75 inches), with about thirty-two (32) LED strips disposed in parallel evenly at a 50 mm pixel pitch across the height (H) at a 50 mm horizontal pixel pitch.

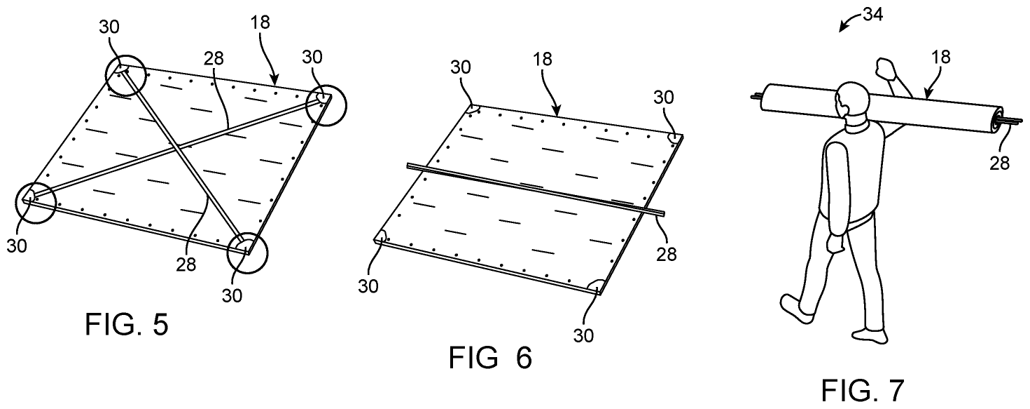

FIG. 5-7 illustrate a sequence of steps for disassembling and preparing panels 18 for transport. After a drape 12 or wall-hung display 12A is removed from its supporting structure, or alternatively while still on the supporting structure, individual panels are separated by detaching the panel-to-panel connectors, such as hook & loop fasteners 24 and additional connections via reinforced holes 32 if used. Electrical connections (hereinafter described) are also disconnected as appropriate for the connection type. Thereafter, stretching members 28 are removed or detached from corner pieces 30 and pivoted together to the middle of panel 18. Rolled panels 34 for transport and storage are then formed simply by rolling fabric substrate 22 around parallel stretching members 28. Rolling is preferably done with LED strips 20 lying parallel to stretching members 28. Rolled panels 34 are compact and light enough to be easily carried by an individual as shown in FIG. 7.

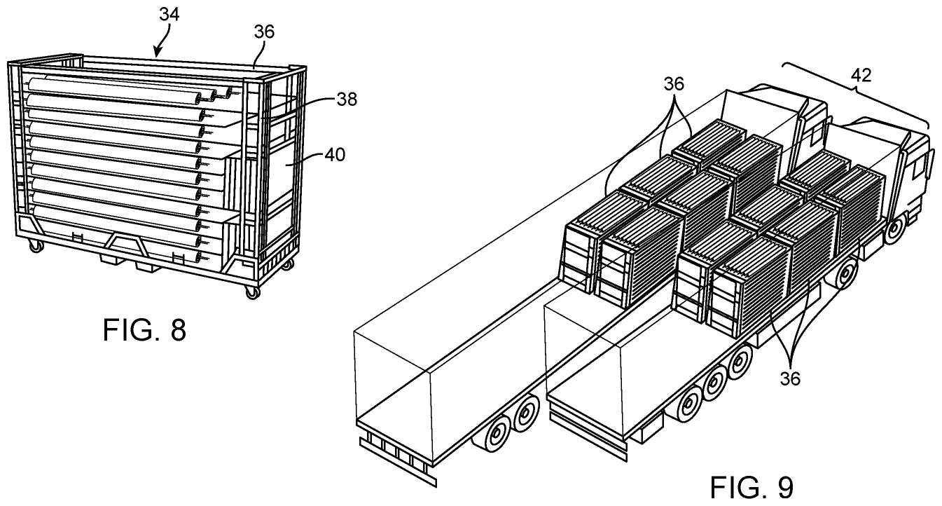

As shown on FIG. 8, anywhere from thirty to sixty rolled panels 34 may be conveniently placed in dollies 36 for storage and transport. For panels 18, sized at 1.6 m high×2 m wide, forty-four (44) rolled panels 34 may be stored in dolly 36 that is approximately 2166 mm high×3000 mm wide×1143 mm deep, while also providing spaces 38 for cabling, accessories and power supplies 40. With these dimensions as examples, as many as 8-10 dollies 36 may be transported by standard transport trucks 42, as shown on FIG. 9, depending on truck size/capacity.

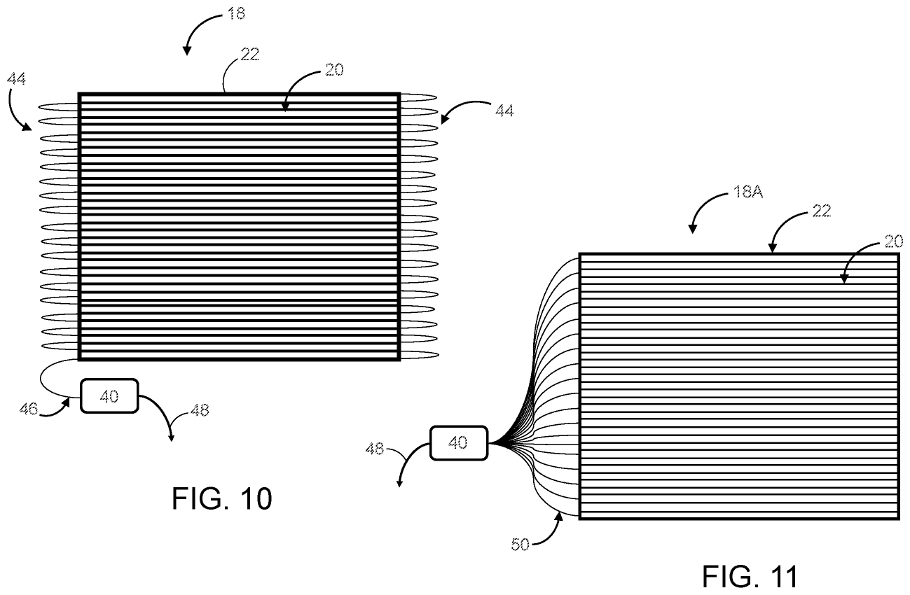

Electrical connections for distribution of power and video data to LED strips 20 may be devised by persons of ordinary skill based on the teachings of the present disclosure, including the examples of FIGS. 10 and 11. In FIG. 10, flexible panel 18 uses serial electrical connectors 44 to connect each LED strip 20 to the preceding and following LED strip 20 in a daisy-chain-like manner. Serial connections may also be made by alternating rows in various patterns or sequences. Cable 46 connects the final LED strip in this configuration to video data supply and power supply 40, which is in turn connected to sources via cable 48. In one alternative embodiment, panel 18A uses parallel electrical connectors 50 to connect each LED strip 20 to video data and power supply 40. Alternatively, a combination of the two above approaches may be used with any number of LED strips grouped together via serial connectors 44 and then each such group linked to video data supply and power supply 40 via parallel connectors 50. Any of the foregoing hard-wired data links may be replaced by appropriately sized wireless data links using known wireless communications protocols.

The foregoing has been a detailed description of illustrative embodiments of the disclosure. It is noted that in the present specification and claims appended hereto, conjunctive language such as is used in the phrases “at least one of X, Y and Z” and “one or more of X, Y, and Z,” unless specifically stated or indicated otherwise, shall be taken to mean that each item in the conjunctive list can be present in any number exclusive of every other item in the list or in any number in combination with any or all other item(s) in the conjunctive list, each of which may also be present in any number. Applying this general rule, the conjunctive phrases in the foregoing examples in which the conjunctive list consists of X, Y, and Z shall each encompass: one or more of X; one or more of Y; one or more of Z; one or more of X and one or more of Y; one or more of Y and one or more of Z; one or more of X and one or more of Z; and one or more of X, one or more of Y and one or more of Z.

Various modifications and additions can be made without departing from the spirit and scope of this disclosure. Features of each of the various embodiments described above may be combined with features of other described embodiments as appropriate in order to provide a multiplicity of feature combinations in associated new embodiments. Furthermore, while the foregoing describes a number of separate embodiments, what has been described herein is merely illustrative of the application of the principles of the present disclosure. Additionally, although particular methods herein may be illustrated and/or described as being performed in a specific order, the ordering is highly variable within ordinary skill to achieve aspects of the present disclosure. Accordingly, this description is meant to be taken only by way of example, and not to otherwise limit the scope of this disclosure or of the inventions as set forth in following claims.

1. Adaptable video displays comprised of one or more flexible display panels, each panel comprising:
a flexible, foldable and rollable substrate having edges with corners;
stretcher connectors disposed at each corner on a back side of said substrate;
at least two stretching members configured to extend between opposite stretcher connectors to hold said substrate in a flat, substantially taught state;
flexible LED strips disposed on a front side of said substrate forming an array of LED pixels along the front side surface of said substrate;
panel-to-panel connectors along each panel edge; and
one or more data and power links communicating with said flexible LED strips.

2. The display of claim 1, wherein said panel-to-panel connectors comprise at least one of hook and loop fasteners and reinforced openings.

3. The display of claim 1, wherein said at least two stretching members are rotatably pinned together.

4. The display of claim 3, wherein said stretcher connectors comprise pockets.

5. The display of claim 4, wherein said flexible, foldable, rollable substrate comprises a fabric material.

6. The display of claim 5, wherein the fabric material comprises one or more of polyester, canvas, nylon, polyethylene and polypropylene

7. The display of claim 1, further comprising at least one power supply communicating with the LED strips of at least one said flexible display panel through said data and power links.

8. An adaptable video display system, comprising:
a plurality of flexible display panels according to any of claims 1-6, said panels joinable along panel edges in an array to form a video display;
a plurality of power supplies, each power supply connectable with at least one said flexible display panel via said data and power links; and
a plurality of storage and transport dollies, each dolly mounted on wheels and configured to carry thirty to sixty rolled up flexible display panels and power supplies for at least every two flexible display panels carried by the dolly.

9. The adaptable video display system of claim 8, wherein:
each flexible display panel is approximately 1.6 m high×2 m wide;
one power supply communicates with each flexible display panel; and
each said storage and transport dolly is configured to contain forty-four rolled up display panels and forty-four power supplies.

10. The adaptable video display system of claim 9, wherein each said dolly is not larger than approximately 2166 mm high×3000 mm wide×1143 mm deep.

11. A method for deploying a video display, comprising:
providing a plurality of flexible display panels, each said flexible display panel having a flexible LED array on a front side and stretcher connectors in corners on a back side;
expanding and stiffening each flexible display panel by placing stretching members in opposed stretcher connectors on each said flexible panel;
connecting the flexible display panels along panel edges to form a video display comprised of an array of the plurality of flexible display panels; and
positioning said video display as a drape across a plurality of stadium or theater seats, or alternatively hanging said video display in a vertical configuration from a support structure.

12. The method of claim 11, further comprising connecting power supplies to said flexible display panels using data and power links.

13. The method of claim 12, further comprising disassembling said video display for transport or storage, said disassembling comprising:
disconnecting the connected flexible display panels;
disconnecting the power supplies and data and power links;
removing the stretching members from the stretcher connectors;
rolling each flexible display panel around removed stretching members;
placing a plurality of rolled flexible display panels on a storage and transport dolly; and
placing power supplies disconnected from the flexible display panels on the storage and transport dolly also on said storage and transport dolly.

14. The method of claim 13, further comprising:
transporting plural said storage and transport dollies to a new display location;
removing said rolled flexible display panels and said power supplies from the storage and transport dollies at the new display location; and
repeating said providing, expanding and stiffening, connecting and positioning steps at said new location.
